(19) United States
(12) Patent Application Publication
(10) Pub. No.: US 2012/0019262 A1
(43) Pub. Date: Jan. 26, 2012

(54) TIME DIFFERENCE MEASUREMENT APPARATUS

(75) Inventors: Xu Zhang, Kawasaki (JP); Motohiro Ozawa, Kawasaki (JP); Yoshihiko Satsukawa, Kawasaki (JP)

(73) Assignee: FUJITSU LIMITED, Kawasaki-shi (JP)

(21) Appl. No.: 13/010,092

(22) Filed: Jan. 20, 2011

(30) Foreign Application Priority Data
Jan. 25, 2010 (JP) 2010-013603

(51) Int. Cl. G01R 27/28

(52) U.S. Cl. 324/617

(57) ABSTRACT

A time difference measurement apparatus for measuring a time difference between transmission delay times of signals transmitted on two signal lines, includes: a selector for outputting one of the signals transmitted on the signal lines in accordance with a selection signal; a switch for outputting the selection signal in accordance with an output signal of the selector, the output signal being delayed for a predetermined time; a feedback loop for connecting the output of the selector to the input ends of the two signal lines; and a controller for calculating a time difference between transmission delay times of the signals transmitted on the two signal lines on the basis of self-oscillation cycles of signals transmitted through the feedback loop, the self-oscillation cycles changing in accordance with a logical value of the selection signal.

### CROSS-REFERENCE TO RELATED APPLICATION

This application is based upon and claims the benefit of priority of the prior Japanese Patent Application No. 2010-013603 filed on Jan. 25, 2010, the entire contents of which are incorporated herein by reference.

### FIELD

The embodiments discussed herein are related to a time difference measurement apparatus for measuring the time difference between transmission delay times between signals that are transmitted on two signal lines.

### BACKGROUND

In the design of a synchronization integrated circuit system, a clock signal is supplied from the same clock source to a plurality of cells that are configured as function blocks on an integrated circuit. In order to supply a clock signal having an appropriate and stable waveform to a large number of cells, a method for dividing a signal line, on which a clock signal output from the clock source is transmitted, into signal lines via buffers or inverters, which are provided at some stages, to obtain clock signals that are transmitted on the signal lines, and for supplying the clock signals has been used as a common method. An inverter is a logical inversion circuit that inverts the logical value of an input signal to obtain an inverted signal, and that outputs the inverted signal.

When the number of logical inversion circuits that are inserted is the same, it is desirable that timings at which the clock signals are supplied to the individual cells be the same or desired timings. However, there is a case in which transmission delay times of the clock signals that are transmitted on two signal lines are not the same because of a process variation in the production process of the integrated circuit, a variation in a power supply voltage, or a variation in the amount of heat at a time of operation of the integrated circuit. The difference between the transmission delay times of the clock signals is called a clock skew. When the clock skew exceeds an allowable value of the amount of skew between operation timings of two of the cells, the possibility of the integrated circuit malfunction increases.

In order to evaluate the clock skew between the two clock signals at a time of operation of the integrated circuit, the outputs of the two signal lines are fed back to the inputs of the individual signal lines, thereby forming feedback loops. Because each of the feedback loops includes a plurality of inverters, when the number of inverters is an odd number, the inverters operate as a ring oscillator. The self-oscillation cycle of each of the ring oscillators depends on the transmission delay time of a signal that is transmitted on a corresponding one of the signal lines. Accordingly, the difference between the transmission delay times of the signals that are transmitted on the signal lines can be obtained using the difference between the self-oscillation cycles of the ring oscillators that are formed along the individual paths. In Japanese Laid-Open Patent Publications No. 10-163819, No. 10-300821, and No. 2008-510428, technologies regarding transmission delays of signals that are transmitted through circuits are discussed.

However, regarding signal transmission characteristics of transistors that are configured as an inverter, the signal transmission characteristics in a case in which the voltage value of an input signal is low is different from the signal transmission characteristics in a case in which the voltage value of the input signal is high. It is impossible to consider, using the difference between the self-oscillation cycles of the ring oscillators that are formed along the individual paths, the difference between the signal transmission characteristics in which a signal having a low level is transmitted and the signal transmission characteristics in which a signal having a high level is transmitted.

### SUMMARY

According to an aspect of the embodiment, a time difference measurement apparatus for measuring a time difference between transmission delay times of signals transmitted on two signal lines, includes: a selector for outputting one of the signals transmitted on the signal lines in accordance with a selection signal; a switch for outputting the selection signal in accordance with an output signal of the selector, the output signal being delayed for a predetermined time; a feedback loop for connecting the output of the selector to the input ends of the two signal lines; and a controller for calculating a time difference between transmission delay times of the signals transmitted on the two signal lines on the basis of self-oscillation cycles of signals transmitted through the feedback loop, the self-oscillation cycles changing in accordance with a logical value of the selection signal.

The object and advantages of the embodiment will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of an integrated circuit;

FIG. 2 is a circuit diagram of a clock extraction circuit;

FIG. 3 is a waveform diagram of input signals and an output signal of a multiplexer in a first mode;

FIG. 4 is a circuit diagram of a clock extraction circuit;

FIG. 5 is a timing diagram of a switch in the first mode;

FIG. 6 is a circuit diagram of a time difference adjustment circuit;

FIG. 7 is a flowchart of a process performed by a controller;

FIG. 8 is a block diagram of the controller;

FIG. 9 is an adjustment table that is stored in a comparator;

FIG. 10A is a circuit diagram of a delay adjustment unit;

FIG. 10B is a delay setting table;

FIG. 11 is a circuit diagram of a delay adjustment unit; and

FIG. 12 is a circuit diagram of a delay adjustment unit.

### DESCRIPTION OF EMBODIMENTS

Hereinafter, embodiments of the present invention will be described. Note that combinations of configurations in the individual embodiments are included in the embodiments of the present invention.

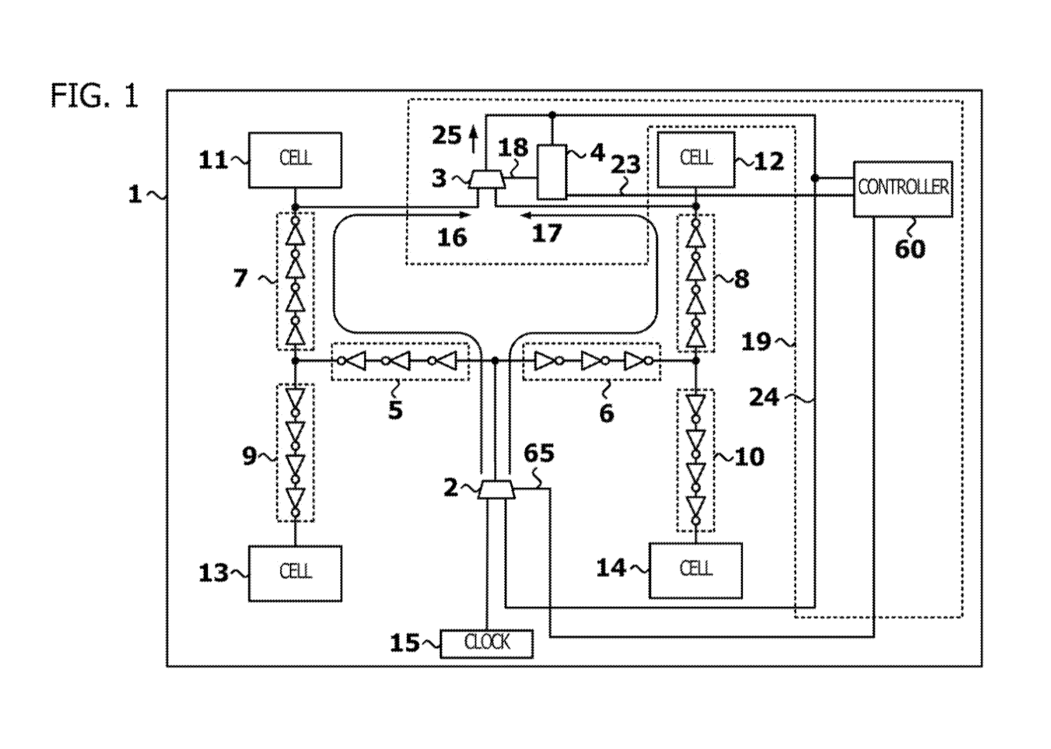

FIG. 1 is a block diagram of an integrated circuit 1 when a clock distribution system is focused on. The integrated circuit 1 includes cells 11 to 14, a clock source 15, delay circuits 5 to 10, a time difference measurement apparatus 19, and a multiplexer 2.

The individual cells 11 to 14 are circuits configured to have functions different from one another. In the present embodiment, the cells 11 to 14 operate so that the cells are synchronized with one another using a clock signal that is output from the same clock source.

The clock source 15 supplies a clock signal to the cells 11 to 14. The delay circuits 5 to 10 have a plurality of inverters therein, and the clock signal that is supplied from the clock source 15 is delayed in accordance with the number of inverters.

A clock signal 16 is a signal that is transmitted on a signal line on which the delay circuits 5 and 7 are provided, and that is input to a multiplexer 3. A clock signal 17 is a signal that is transmitted on a signal line on which the delay circuits 6 and 8 are provided, and that is input to the multiplexer 3.

The time difference measurement apparatus 19 measures the time difference between transmission delay times of the two clock signals 16 and 17. The time difference measurement apparatus 19 includes the multiplexer 3, a switch 4, a feedback loop 24, and a controller 60.

The multiplexer 3 is connected to a side, from which signals are output, of the two signal lines on which the clock signals 16 and 17 are transmitted. Accordingly, the multiplexer 3 takes, as inputs, the clock signal 16 that is supplied to the cell 11 and the clock signal 17 that is supplied to the cell 12. The multiplexer 3 operates as a selector that outputs, in accordance with a selection signal 18, either of the clock signals that are transmitted on the signal lines.

The switch 4 is connected to a side, from which a signal is output, of the multiplexer 3. The switch 4 delays an output signal of the multiplexer 3 by a fixed time to obtain a delayed signal, and outputs the delayed signal as the selection signal 18. The switch 4 switches between two operation modes in accordance with a switching signal 23 that is input thereto. In a first mode, the switch 4 receives an output signal 25 of the multiplexer 3, delays the output signal 25 by a fixed time to obtain a delayed signal, and outputs the delayed signal as the selection signal 18. The fixed time by which the output signal 25 is delayed by the switch 4 is longer than the clock skew between the clock signals 16 and 17 that has been measured since the change of the logical value of the output signal 25 of the multiplexer 3. In the second mode, the switch 4 outputs the selection signal 18 so that either of the clock signals is always selected and output. Each of the operation modes will be described in detail below.

The feedback loop 24 is formed using a wiring line for providing the output of the multiplexer 3 as one of two inputs of the multiplexer 2.

The multiplexer 2 switches between a mode in which a clock signal is supplied from the clock source 15 to each of the cells in accordance with the logical value of the selection signal 65, and a mode in which the clock skew between two signal lines is measured. The multiplexer 2 receives, as one of the two inputs, the clock signal that has been supplied from the clock source 15, and receives, as the other input, a signal that has been transmitted through the feedback loop 24. When the logical value of the selection signal 65 is “0”, the multiplexer 2 outputs the clock signal that has been received from the clock source 15, and, when the logical value of the selection signal 65 is “1”, the multiplexer 2 outputs a signal that has been transmitted through the feedback loop 24. The logical value of the selection signal 65 of the multiplexer 2 may be controlled by the controller 60 as in the present embodiment, or may be controlled by a unit that is provided outside the integrated circuit 1.

When the number of inverters that are provided along a path from the output of the multiplexer 2 to one of the inputs of the multiplexer 3 is an odd number, a ring oscillator is formed using the feedback loop 24. In the ring oscillator, self-oscillation of a signal having a cycle that is determined in accordance with a delay time of the signal which is transmitted along the path from the output of the multiplexer 2 to the input of the multiplexer 3 is generated. When the number of inverters that are provided along the path from the output of the multiplexer 2 to the input of the multiplexer 3 is an even number, the logic polarity of a path from the output of the multiplexer 3 to the multiplexer 2 is inverted, for example, by inserting one inverter into the output of the multiplexer 3. In this manner, a ring oscillator is formed.

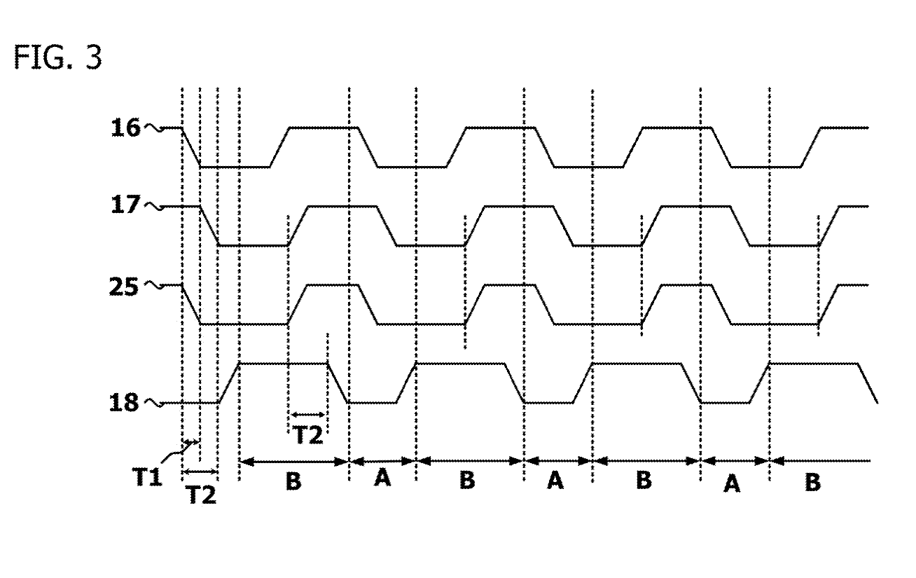

The controller 60 is connected to the feedback loop 24, and calculates, on the basis of self-oscillation cycles of signals that are transmitted through the feedback loop 24, the time difference between the transmission delay times of the clock signals 16 and 17 that are transmitted on the two signal lines. The controller 60 outputs the switching signal 23 for switching the operation mode of the switch 4. The controller 60 measures, using the switching signal 23, the self-oscillation cycle of a signal that is transmitted through the feedback loop 24 in accordance with each operation mode. The controller 60 calculates the difference between the individual self-oscillation cycles that have been measured, whereby the controller 60 can measure the time difference between the transmission delay times of the clock signals 16 and 17. A specific method for measuring the time difference between the transmission delay times will be described below with reference to FIG. 3. The controller 60 can also measure the time difference between the transmission delay times by storing a reference value that is set in advance and by calculating the difference between the self-oscillation cycle that has been measured in either of the operation modes and the reference value.

In the controller 60, a function of measuring the self-oscillation cycle of a signal that is transmitted through the feedback loop 24 may be implemented as a measurement unit that is provided outside the integrated circuit 1.

As described above, the time difference between the transmission delay times of the two clock signals 16 and 17 can be measured by selecting the two clock signals 16 and 17 and by forming a feedback loop via a clock extraction circuit.

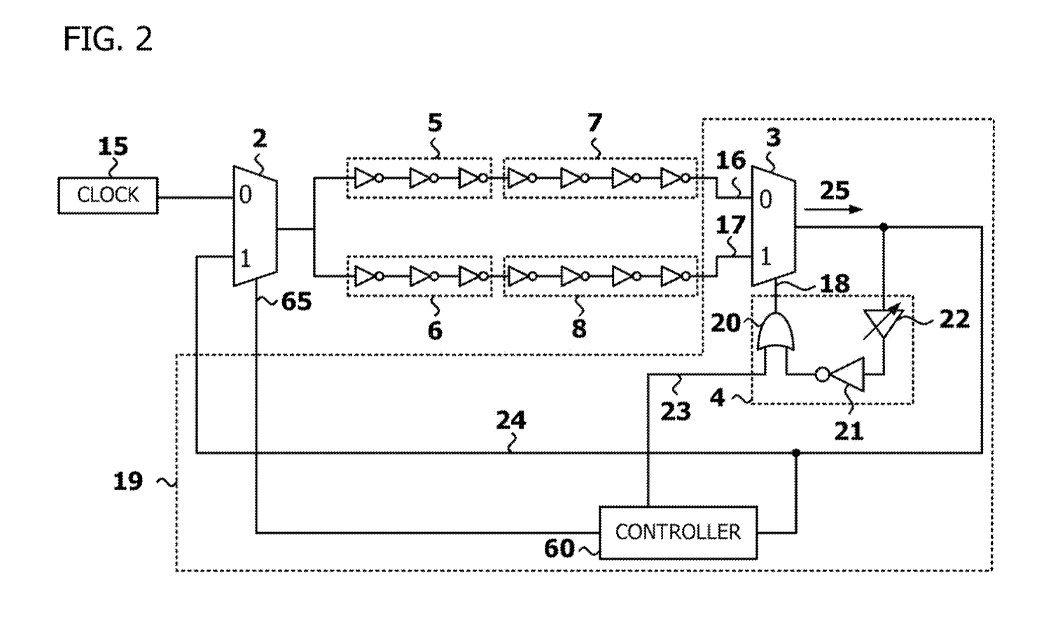

FIG. 2 is a circuit diagram of the clock extraction circuit including the time difference measurement apparatus 19. In the time difference measurement apparatus 19 illustrated in FIG. 2, the switch 4 includes an OR circuit 20, an inverter 21, and a delay buffer 22. In FIG. 2, components that are the same as those of the integrated circuit 1 illustrated in FIG. 1 are denoted by the same reference numerals, and a description thereof is omitted.

The delay buffer 22 delays the output signal 25, which has been output from the multiplexer 3 to the feedback loop 24, by a fixed time, which is referred to as a “delay time” of the delay buffer 22, without changing the logical value of the output signal 25, and outputs the output signal 25 that has been delayed. It is supposed that the delay time of the delay buffer 22 is longer than the clock skew between the clock signals 16 and 17. A configuration in which the delay time of the delay buffer 22 can be adjusted using an external unit may be used. The inverter 21, which is described below, can be omitted using an inverter having a fixed delay time instead of the delay buffer 22.

The inverter 21 inverts the logical value of the output signal 25, which has been output from the delay buffer 22, to obtain an inverted signal, and outputs the inverted signal. The OR circuit 20 takes the switching signal 23 as one of two inputs, and takes, as the other input, the inverted signal that has been output from the inverter 21. The OR circuit 20 outputs the logical sum of the two input signals as the selection signal 18.

When the logical value of either of the inputs of the OR circuit 20 is “1”, the OR circuit 20 outputs the selection signal 18 whose logical value is “1”. Accordingly, by setting the logical value of the switching signal 23 to “1”, the switch 4 operates in the above-described second mode.

By setting the logical value of the switching signal 23 to “0”, the logical value of the selection signal 18 that is to be output from the OR circuit 20 changes in accordance with the logical value of the signal that is obtained by delaying the output signal 25 of the multiplexer 3 by the fixed time to obtain a delayed signal and by inverting the delayed signal. In a case in which the logical value of the switching signal 23 is “0”, when the fixed time has elapsed since the change of the logical value of the output signal 25 of the multiplexer 3, the switch 4 outputs the selection signal 18 for switching the output signal 25. Accordingly, the switch 4 operates in the above-described first mode.

As described above, switching between the clock signals 16 and 17, each of which is to be output as the output signal 25, in an alternating manner can be performed by changing the logical value of the selection signal 18 when the fixed time has elapsed since the transition of the output signal 25.

FIG. 3 is a waveform diagram of the input signals and the output signal of the multiplexer 3 in the first mode. A waveform 16 is a voltage waveform of the clock signal 16. A waveform 17 is a voltage waveform of the clock signal 17. A waveform 25 is a voltage waveform of the output signal 25 that is output to the feedback loop 24. A waveform 18 is a voltage waveform of the selection signal 18. Here, the waveforms 16 and 17 are waveforms of the input signals of the multiplexer 3 supposing that the same signal has been input from the multiplexer 2 to the delay circuits 5 and 6. The waveform 25 is a waveform supposing that the waveforms 16 and 17 of the clock signals 16 and 17 which are input to the multiplexer 3 are the waveforms illustrated in FIG. 3.

In FIG. 3, a time T1 is the clock skew between the clock signals 16 and 17. In the present embodiment, the phase of the clock signal 16 is the time T1 ahead of the phase of the clock signal 17. A time T2 is a delay time of the delay buffer 22. Assuming that the time T1 is a certain time, the time T2 is set to a value that is longer than the time T1.

The controller 60 outputs the switching signal 23 for setting the operation mode of the switch 4 to the first mode. Because the logical value of the selection signal 18 that is output from the switch 4 is “0” at first, the multiplexer 3 selects the clock signal 16. The multiplexer 3 outputs the clock signal 16 as the output signal 25. When the time T2 has elapsed since the start of transition of the logical value of the clock signal 16 from “1” to “0”, the logical value of the selection signal 18 starts changing from “0” to “1”. When the logical value of the selection signal 18 becomes “1” in an interval B, the multiplexer 3 selects the clock signal 17, and outputs the clock signal 17 as the output signal 25.

When the time T2 has elapsed since the start of transition of the logical value of the output signal 25 from “0” to “1”, the logical value of the selection signal 18 starts changing from “1” to “0”. When the logical value of the selection signal 18 becomes “0” in an interval A, the multiplexer 3 selects the clock signal 16, and outputs the clock signal 16 as the output signal 25.

When the clock signal 16 whose logical value changes from “1” to “0” is transmitted through the delay circuits 5 and 7 in the interval A, a transmission delay time of the clock signal 16 is denoted by D0dn. When the clock signal 17 whose logical value changes from “0” to “1” is transmitted through the delay circuits 6 and 8 in the interval B, a transmission delay time of the clock signal 17 is denoted by D1up. When the clock signal 16 whose logical value changes from “1” to “0” is transmitted through the feedback loop 24 in the interval A, a transmission delay time of the clock signal 16 is denoted by DCdn. When the clock signal 17 whose logical value changes from “0” to “1” is transmitted through the feedback loop 24 in the interval B, a transmission delay time of the clock signal 17 is denoted by DCup. In this case, a self-oscillation cycle TV1 of a ring oscillator in the first mode is represented by an equation TV1=D0dn+D1up+DCdn+DCup.

The controller 60 is connected to the feedback loop 24. The controller 60 measures the self-oscillation cycle TV1 of the signal that is transmitted through the feedback loop 24 in the first mode. For example, the controller 60 has a pulse generator that generates pulses having a cycle which is much shorter than the self-oscillation cycle TV1, and a counter that counts the number of pulses which are output from the pulse generator. The controller 60 can measure the self-oscillation cycle TV1 by counting the number of pulses per cycle of the output signal 25 of the multiplexer 3. The controller 60 temporarily stores the self-oscillation cycle TV1 that has been measured.

Then, the controller 60 outputs the switching signal 23 for switching the operation mode of the switch 4 to the second mode. In the second mode, when the clock signal 17 whose logical value changes from “1” to “0” is transmitted through the delay circuits 6 and 8, a transmission delay time of the clock signal 17 is denoted by D1dn. When the clock signal 17 whose logical value changes from “0” to “1” is transmitted through the delay circuits 6 and 8, a transmission delay time of the clock signal 17 is denoted by D1up. When any of the clock signals 16 and 17 is transmitted through the feedback loop 24, a transmission delay time of the clock signal whose logical value changes from “1” to “0” and a transmission delay time of the clock signal whose logical value changes from “0” to “1” do not change. Accordingly, similarly to the transmission delay times in the first mode, transmission delay times in the second mode are DCdn and DCup. Accordingly, a self-oscillation cycle TV2 in the second mode is represented by an equation TV2=D1dn+D1up+DCdn+DCup. As in the case of measurement of the self-oscillation cycle TV1 in the first mode, the controller 60 measures the self-oscillation cycle TV2 of a signal that is transmitted through the feedback loop 24 in the second mode.

A clock skew SK that is the time difference between the transmission delay times of the clock signals 16 and 17 can be obtained by calculating the difference between the self-oscillation cycles TV1 and TV2. Accordingly, the clock skew SK is represented by an equation SK=(D0dn+D1up+DCdn+DCup)−(D1dn+D1up+DCdn+DCup)=D0dn−D1dn. In other words, the clock skew SK is the difference between the transmission delay times of the clock signals 16 and 17 in a case in which the clock signals 16 and 17 whose logical values change from “1” to “0” are transmitted through the delay circuits 5 and 7 and the delay circuits 6 and 8, respectively. The controller 60 performs a process of subtracting the self-oscillation cycle TV2, which has been measured, from the self-oscillation cycle TV1, which is temporarily stored, whereby the controller 60 can calculate the clock skew SK that is the time difference between the transmission delay times.

As described above, the clock signal 17 whose logical value changes from “0” to “1” and the clock signal 16 whose logical value changes from “1” to “0” are mixed together to obtain a mixed signal, self-oscillation of the mixed signal is generated, and the self-oscillation cycle of the mixed signal is obtained. Only the clock signal 17 is caused to be transmitted, self-oscillation of the clock signal 17 is generated, and the self-oscillation cycle of the clock signal 17 is obtained. The difference between the self-oscillation cycles is calculated, whereby the clock skew between transition timings at which the logical values of the two clock signals individually change from “1” to “0” can be obtained. An accurate time difference between the transmission delay times of the two clock signals can be obtained in accordance with edges of the individual clock signals by comparing the transition timings at which the same transition occurs in the two clock signals.

In a case in which the cells 11 and 12 operate using falling edges of the clock signals as triggers, necessary adjustment amounts of the transmission delay times of the clock signals can be accurately calculated by obtaining the time difference between the transmission delay times in accordance with the falling edges of the individual clock signals as described in the present embodiment. The time difference between transmission delay times of the clock signals can be obtained in accordance with rising edges using the same method by changing timing at which switching is performed by the multiplexer 3 in the first mode and by changing a signal line for generating self-oscillation in the second mode. By obtaining the time difference between the transmission delay times in accordance with the rising edges, necessary adjustment amounts of the transmission delay times of the clock signals in a case in which the cells 11 and 12 operate using the rising edges of the clock signals as triggers can be accurately calculated.

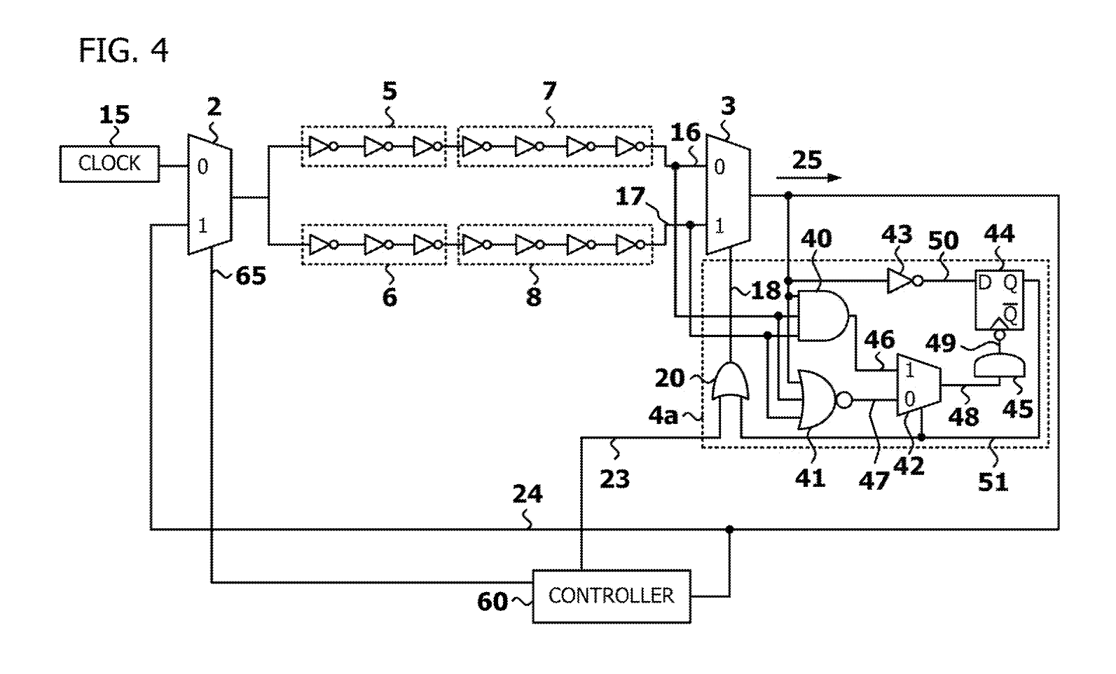

FIG. 4 is a circuit diagram of a clock extraction circuit including a time difference measurement apparatus in which the switch 4 has been replaced with the switch 4a. The switch 4a includes an OR circuit 20, an AND circuit 40, a NOR circuit 41, a multiplexer 42, an inverter 43, a chopper circuit 45, and a latch circuit 44. In the circuit diagram illustrated in FIG. 4, components that are the same as those illustrated in FIG. 2 are denoted by the same reference numerals, and a description thereof is omitted.

The AND circuit 40 takes as inputs, clock signals 16 and 17, which are input to the multiplexer 3, and the output signal 25, and outputs the logical product of the signals as an output signal 46. When the logical value of one signal among the three input signals is “0”, the logical value of the output signal 46 becomes “0”. When the logical values of all of the input signals are “1”, the logical value of the output signal 46 becomes “1”.

The NOR circuit 41 takes, as inputs, the clock signals 16 and 17, which are input to the multiplexer 3, and the output signal 25, performs nondisjunction of the signals to obtain an inverted signal, and outputs the inverted signal as an output signal 47. When the logical value of one signal among the three input signals is “1”, the logical value of the output signal 47 becomes “0”. When the logical values of all of the input signals are “0”, the logical value of the output signal 47 becomes “1”.

The multiplexer 42 selects either the output signal 46 of the AND circuit 40 or the output signal 47 of the NOR circuit 41 in accordance with the logical value of an output signal 51 of the latch circuit 44, and outputs the selected signal as an output signal 48. When the logical value of the output signal 51 is “1”, the multiplexer 42 selects the output signal 46 of the AND circuit 40. When the logical value of the output signal 51 is “0”, the multiplexer 42 selects the output signal 47 of the NOR circuit 41.

The inverter 43 outputs, to the latch circuit 44, as an output signal 50, a signal that is obtained by inverting the logical value of the output signal 25 of the multiplexer 3.

When the logical value of the output signal 48 that is output from the multiplexer 42 changes from “0” to “1”, the chopper circuit 45 holds the logical value of the output signal 49 for a fixed time so that the logical value is “1”.

When the logical value of the output signal 49 is “1”, the latch circuit 44 outputs, as the output signal 51, a signal whose logical value is the same as the logical value of the output signal 50 that has been input. When the logical value of the output signal 49 changes from “1” to “0”, the latch circuit 44 continues outputting, as the output signal 51, a signal whose logical value is the same as the logical value of the output signal 50 that has been input before the logical value of the output signal 49 changes. Note that an equivalent operation can be realized also by replacing the latch circuit 44 and the chopper circuit 45 with a sequential circuit such as a D-flip-flop.

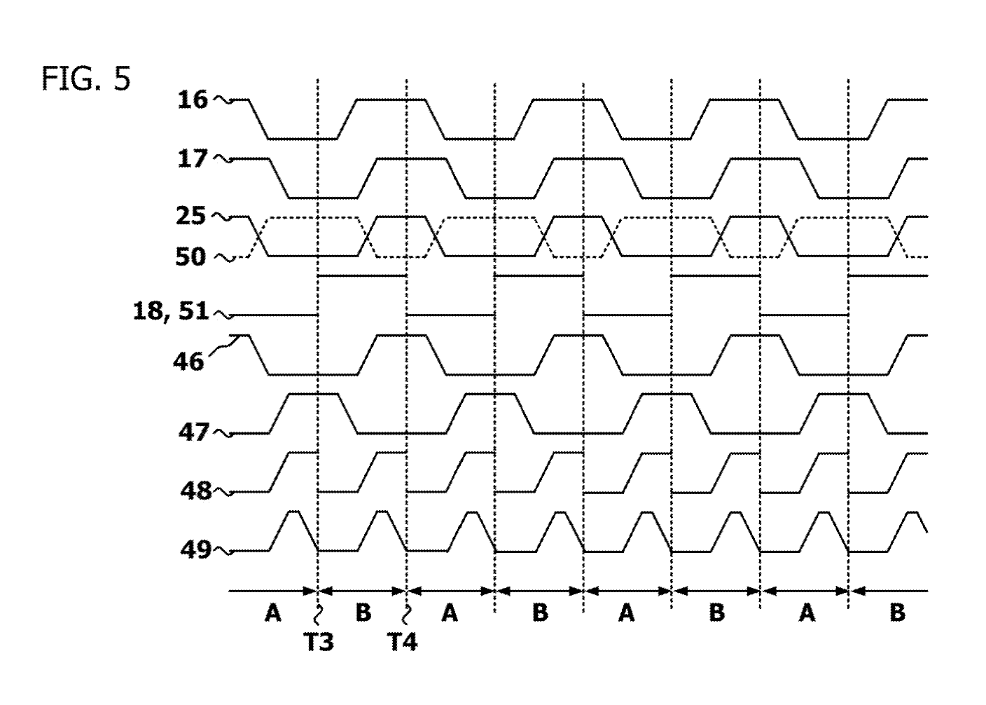

FIG. 5 is a timing diagram of the switch 4a, which is illustrated in FIG. 4, in the first mode. Waveforms 16 and 17 are voltage waveforms of the clock signals 16 and 17, respectively. A waveform 25 is a voltage waveform of the output signal 25. A waveform 50 is a voltage waveform of the output signal 50. A waveform 18 is a voltage waveform of the selection signal 18. A waveform 51 is a voltage waveform of the output signal 51. Waveforms 46 to 49 are voltage waveforms of the output signals 46 to 49, respectively. Hereinafter, the first mode in which the logical value of the switching signal 23 is “0” will be described.

The controller 60 sets, using the switching signal 23, the operation mode of the switch 4a to the first mode. The phase of the clock signal 16 is ahead of the phase of the clock signal 17 as in the timing diagram illustrated in FIG. 3. In the first interval A, the logical value of the selection signal 18 is “0”. Accordingly, in the interval A, the output signal 25 changes at timing that is the same as timing at which the clock signal 16 changes. The inverter 43 inverts the logical value of the output signal 25 to obtain an inverted signal, and outputs the inverted signal as the output signal 50.

When the logical value of one of the input signals of the AND circuit 40 is “0”, the logical value of the output signal 46 of the AND circuit 40 becomes “0”. Accordingly, in the interval A, the logical value of the output signal 46 changes from “1” to “0” at timing that is the same as the timing at which the clock signal 16 changes.

When the logical values of all of the input signals of the NOR circuit 41 are “0, the logical value of the output signal 47 of the NOR circuit 41 becomes “1”. Accordingly, in the interval A, the logical value of the output signal 47 changes from “0” to “1” at timing that is the same as timing at which the clock signal 17 changes.

Because the logical value of the output signal 51 that is a switching signal of the multiplexer 42 is “0” in the interval A, the output signal 48 that is the output signal of the multiplexer 42 changes at timing that is the same as timing at which the output signal 47 changes.

The logical value of the output signal 49 that is the output signal of the chopper circuit 45 becomes “1” at timing at which the logical value of the output signal 48 becomes “1”. The chopper circuit 45 holds the logical value of the output signal 49 for a fixed time so that the logical value is “1”.

At a time T3 at which the logical value of the output signal 49 changes to “0”, the latch circuit 44 continues outputting, as the logical value of the output signal 51, the logical value of the output signal 50 that is input at the time T3. Accordingly, at the time T3, the logical value of the output signal 51 changes to “1” that is a logical value of the output signal 50. The logical value of the selection signal 18 changes to “1” simultaneously with the transition of the output signal 51. The multiplexer 3 switches the output signal 25 to the clock signal 17.

When the logical value of the output signal 51 becomes “1” at the time T3, the multiplexer 42 selects the output signal 46 as the output signal 48. In the interval B, when the logical value of the output signal 48 changes to “1”, the chopper circuit 45 outputs the output signal 49 whose logical value is “1” for a fixed time, and the logical value of the output signal 49 changes to “0” at a time T4.

The latch circuit 44 outputs, as the logical value of the output signal 51, a logical value of “0” that is the logical value of the output signal 50 which is input at the time T4. Because the logical value of the output signal 51 becomes “0”, the switch 4a performs an operation that is similar to the operation performed in the first interval A.

Accordingly, the switch 4a repeats the operations that are performed in the intervals A and B in the first mode, whereby the clock signal 17 whose logical value changes from “0” to “1” and the clock signal 16 whose logical value changes from “1” to “0” can be mixed together. A signal is obtained by alternately switching between the transitions of the two clock signals, and self-oscillation of the signal is generated. The controller 60 measures the self-oscillation cycle TV1 of the signal.

Then, the controller 60 sets, using the switching signal 23, the switch 4a to be in the second mode. In the second mode, the controller 60 measures the self-oscillation cycle TV2 that is obtained by causing only the clock signal 17 to be transmitted and by generating self-oscillation of the clock signal 17. The controller 60 calculates the difference between the self-oscillation cycles TV1 and TV2 that have been measured, whereby the clock skew between transition timings at which the logical values of the two clock signals individually change from “1” to “0” can be obtained.

As described above, the controller 60 can accurately obtain the time difference between the transmission delay times of the two clock signals by comparing the transition timings at which the same transition occurs in the two clock signals. Furthermore, in the switch 4a, the delay buffer 22 for setting a delay time in advance as in the switch 4 is unnecessary. Accordingly, using the switch 4a, the time difference between the transmission delay times of the two clock signals can be accurately measured without assuming in advance that clock skew occurs between the two clock signals.

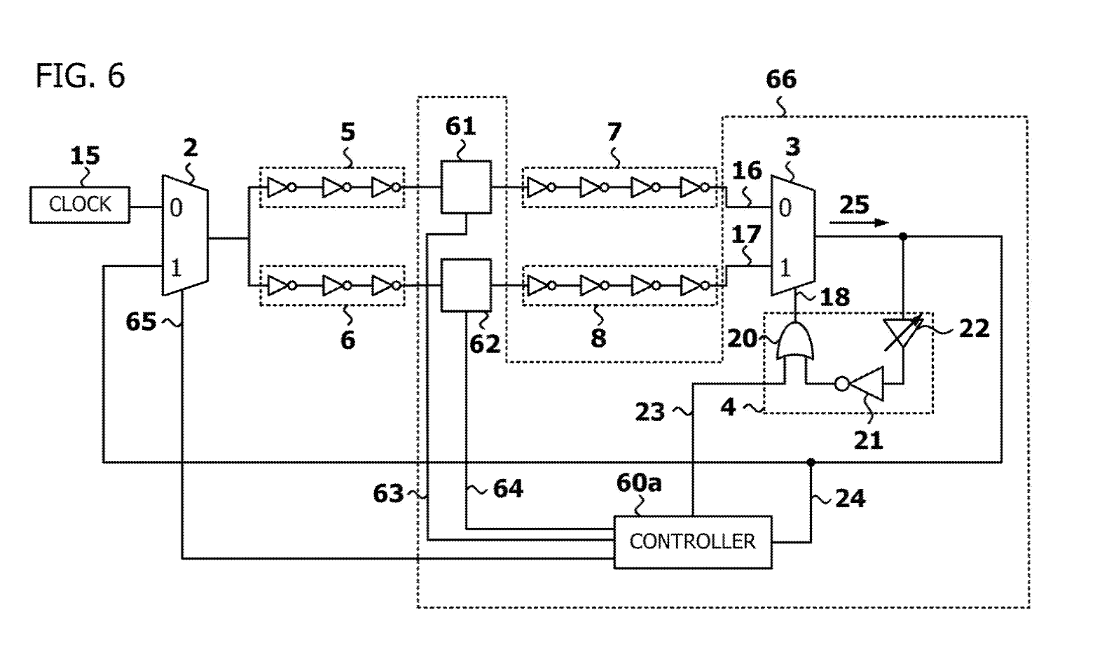

FIG. 6 is a circuit diagram of a time difference adjustment circuit 66. The time difference adjustment circuit 66 performs adjustment of the clock skew on the basis of a result of extraction performed by the time difference measurement apparatus 19. The time difference adjustment circuit 66 includes the time difference measurement apparatus 19, a controller 60a, and delay adjustment units 61 and 62. In FIG. 6, components that are the same as those illustrated in FIG. 2 are denoted by the same reference numerals, and a description thereof is omitted. The switch 4a may be used instead of the switch 4 of the time difference measurement apparatus 19.

The controller 60a sets adjustment amounts of the delay adjustment units 61 and 62 on the basis of a result of extraction of the clock skew. The controller 60a outputs the switching signal 23 for switching the operation mode of the switch 4. The controller 60a is connected to the feedback loop 24, and reads the output signal 25 that is output from the multiplexer 3 in each operation mode. The controller 60a measures the clock skew between the two clock signals 16 and 17 on the basis of the output signal 25 that has been read, and outputs, on the basis of a measurement result, adjustment signals 63 and 64 for adjusting the delay times of the delay adjustment units 61 and 62. Note that the controller 60a is obtained by adding, to the controller 60, a function of setting the delay times of the delay adjustment units 61 and 62 on the basis of the time difference between the transmission delay times that has been measured. The method for measuring a self-oscillation cycle with the controller 60 and a method for measuring a self-oscillation cycle with the controller 60a may be the same.

The delay adjustment units 61 and 62 adjust the delay times on the basis of the adjustment signals 63 and 64 that have been output from the controller 60a. The delay adjustment unit 61 receives an output signal of the delay circuit 5, delays the output signal by a fixed time to obtain a delayed signal, and outputs the delayed signal to the delay circuit 7. The delay adjustment unit 62 receives an output signal of the delay circuit 6, delays the output signal by a fixed time to obtain a delayed signal, and outputs the delayed signal to the delay circuit 8. The details of the delay adjustment units 61 and 62 will be described below.

As described above, the delay times of the clock signals 16 and 17 are adjusted in accordance with a result of measurement of the clock skew, whereby the clock skew between the two clock signals can be reduced.

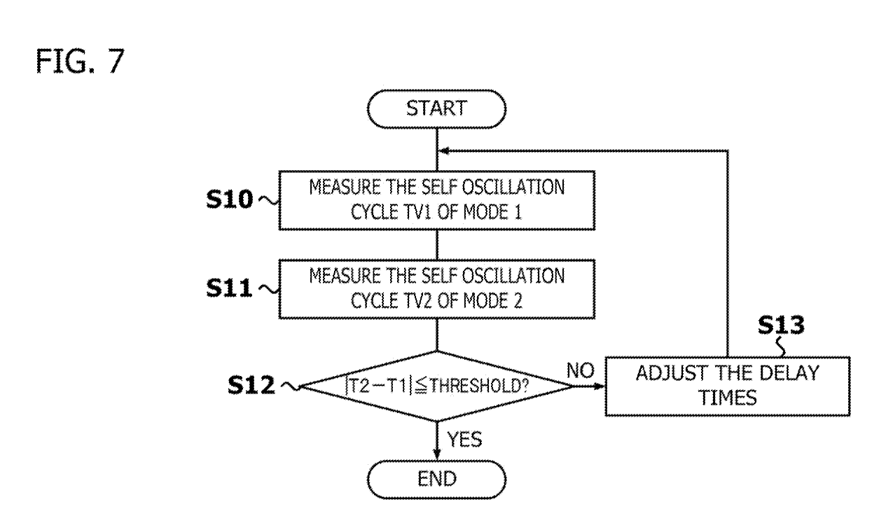

FIG. 7 is a flowchart of a process performed by the controller 60a. The controller 60a sets the logical value of the switching signal 23 to “0”, and sets the operation mode of the switch 4 to the first mode. The controller 60a measures the self-oscillation cycle TV1 of the output signal 25 that is output from the multiplexer 3 in the first mode (step S10).

Then, the controller 60a sets the logical value of the switching signal 23 to “1”, and sets the operation mode of the switch 4 to the second mode. The controller 60a measures the self-oscillation cycle TV2 of the output signal 25 that is output from the multiplexer 3 in the second mode (step S11).

The controller 60a calculates the difference between the self-oscillation cycles TV1 and TV2 that have been measured to obtain a difference value |TV2−TV1|. When the difference value |TV2−TV1| is larger than a threshold that is set in advance (NO in step S12), the controller 60a adjusts the delay times of the delay adjustment units 61 and 62 (step S13). After the controller 60a has adjusted the delay times, the controller 60 repeats the processes in step S10 and thereafter again.

When the difference value |TV2−TV1| is equal to or smaller than the threshold that is set in advance (YES in step S12), the controller 60a finishes the process of adjusting the delay times.

Using the above-described process, the controller 60a can adjust the delay times of the individual clock signals 16 and 17 so that the clock skew between the two clock signals 16 and 17 approaches zero.

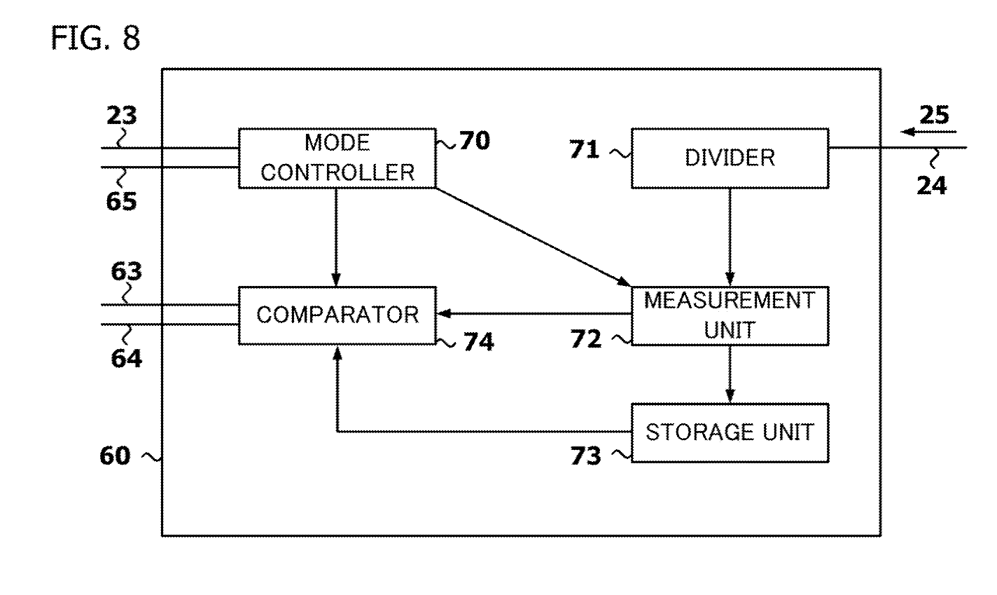

FIG. 8 is a block diagram of the controller 60a. The controller 60a includes a mode controller 70, a divider 71, a measurement unit 72, a storage unit 73, and a comparator 74.

The mode controller 70 outputs the switching signal 23 for switching the operation mode of the switch 4. The mode controller 70 outputs, to the comparator 74 and the measurement unit 72, a signal indicating the current operation mode. The mode controller 70 outputs the selection signal 65.

The divider 71 divides the frequency of the output signal 25 that has been received from the feedback loop 24. Measurement of the self-oscillation cycle of the output signal 25 is facilitated by dividing the frequency of the output signal 25. Note that, when the measurement accuracy of the measurement unit 72 is high, the implementation of the divider 71 is unnecessary.

The measurement unit 72 measures the self-oscillation cycle of the output signal 25 whose frequency has been divided by the divider 71. For the measurement of the self-oscillation cycle, for example, a pulse generator that generates pulses having a cycle which is shorter than the self-oscillation cycle of the output signal 25 and a counter that counts the number of pulses which are output from the pulse generator can be used. When the counter is used, the measurement unit 72 measures the self-oscillation cycle in accordance with the count number of the counter. When operation mode information that the measurement unit 72 has received from the mode controller 70 indicates the first mode, the measurement unit 72 sends a measurement result to the storage unit 73. When the operation mode information that the measurement unit 72 has received from the mode controller 70 indicates the second mode, the measurement unit 72 sends a measurement result to the comparator 74.

The storage unit 73 stores the self-oscillation cycle of the output signal 25 that has been measured by the measurement unit 72 in the first mode. The storage unit 73 sends, to the comparator 74, the self-oscillation cycle that has been stored.

When the operation mode information that the comparator 74 has received from the mode controller 70 indicates the second mode, the comparator 74 compares the self-oscillation cycle of the output signal 25 in the first mode, which has been received from the storage unit 73, with the self-oscillation cycle of the output signal 25 in the second mode, which has been received from the measurement unit 72. The comparator 74 includes an adjustment table for determining the values of the adjustment signals 63 and 64 on the basis of a comparison result. The comparator 74 refers to the adjustment table on the basis of the difference value of the difference between the self-oscillation cycles that were measured in the two operation modes, and determines the values of the adjustment signals 63 and 64. The comparator 74 outputs, to the delay adjustment units 61 and 62, the adjustment signals 63 and 64 that have been determined.

As described above, the controller 60a can set appropriate amounts of delays of the individual clock signals 16 and 17 using the difference between the self-oscillation cycles that were measured in the individual modes.

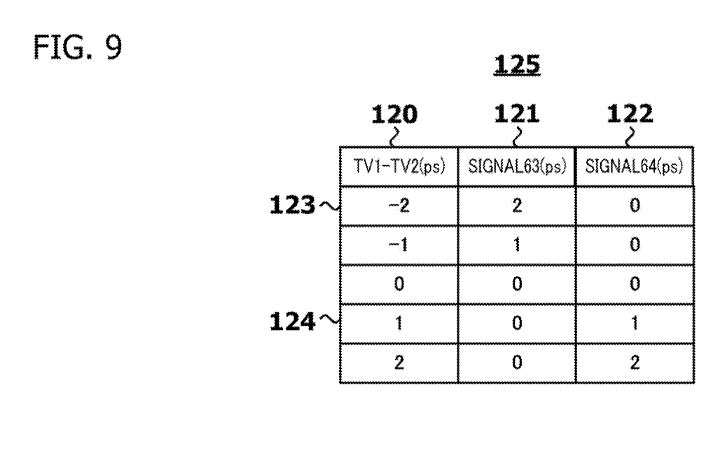

FIG. 9 is an adjustment table 125 that is stored in the comparator 74. In the adjustment table 125, a column 120 indicates the difference value (TV1−TV2) of the difference between the self-oscillation cycle TV1 in the first mode and the self-oscillation cycle TV2 in the second mode. A column 121 indicates the delay time that is set in the delay adjustment unit 61 using the adjustment signal 63 for each difference value. A column 122 indicates the delay time that is set in the delay adjustment unit 62 using the adjustment signal 64 for each difference value.

A row 123 indicates generation of a delay time of 2 ps with the delay adjustment unit 61 using the adjustment signal 63 in a case in which the difference value (TV1−TV2) is −2 ps. As described above, regarding the difference value (TV1−TV2), the equation (TV1−TV2)=D0dn−D1dn is established. When the difference value is positive, the phase of the clock signal 16 is 2 ps ahead of the phase of the clock signal 17. Accordingly, the clock skew between the two clock signals can be reduced to zero by delaying the phase of the clock signal 16 by 2 ps.

A row 124 indicates generation of a delay time of 1 ps with the delay adjustment unit 62 using the adjustment signal 64 in a case in which the difference value (TV1−TV2) is 1 ps. As described above, regarding the difference value (TV1−TV2), the equation (TV1−TV2)=D0dn−D1dn is established. When the difference value is negative, the phase of the clock signal 17 is 1 ps ahead of the phase of the clock signal 16. Accordingly, the clock skew between the two clock signals can be reduced to zero by delaying the phase of the clock signal 17 by 1 ps.

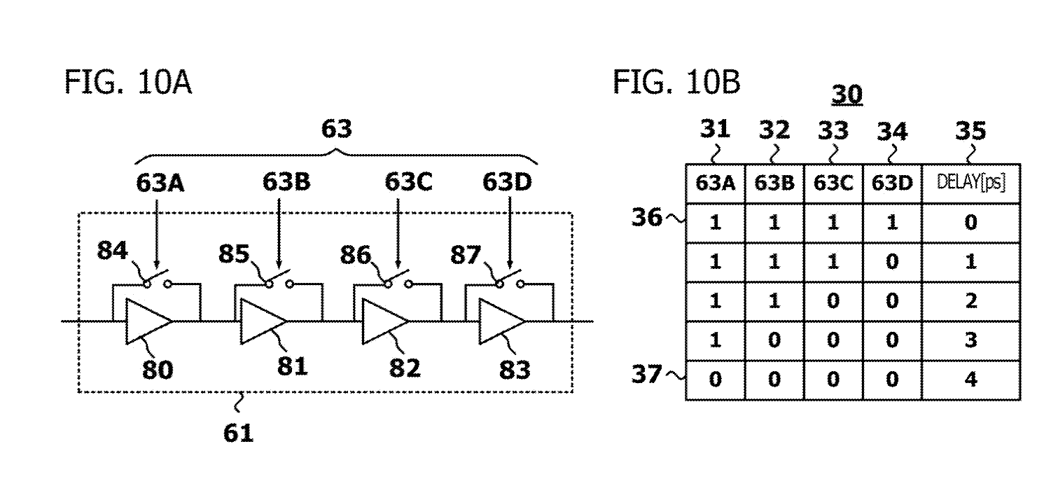

FIGS. 10A and 10B are a circuit diagram of the delay adjustment unit 61 and a delay setting table. FIG. 10A is a circuit diagram of the delay adjustment unit 61. FIG. 10B is a delay setting table of the delay adjustment unit 61. Because the circuit configurations and operations of the delay adjustment units 61 and 62 are the same, a description of the delay adjustment unit 62 is omitted.

In FIG. 10A, the delay adjustment unit 61 includes delay buffers 80 to 83 that are connected in series, and switches 84 to 87 that are connected in parallel to the delay buffers 80 to 83, respectively. Each of the switches 84 to 87 switches the state thereof between an on-state and an off-state in accordance with the logical value of the adjustment signal 63. The adjustment signal 63 is a 4-bit signal constituted by signals 63A to 63D. The switch 84 switches the state thereof between an on-state and an off-state in accordance with the logical value of the signal 63A. The switch 85 switches the state thereof between an on-state and an off-state in accordance with the logical value of the signal 63B. The switch 86 switches the state thereof between an on-state and an off-state in accordance with the logical value of the signal 63C. The switch 87 switches the state thereof between an on-state and an off-state in accordance with the logical value of the signal 63D.

When the switch 84 that is connected in parallel to the delay buffer 80 is in the off-state, the clock signal 16 is transmitted through the delay buffer 80. Because the clock signal 16 is transmitted through the delay buffer 80, the clock signal 16 is delayed by 1 ps. When the switch 84 that is connected in parallel to the delay buffer 80 is in the on-state, the clock signal 16 is transmitted through the switch 84. Because the clock signal 16 is transmitted through the switch 84, the clock signal 16 is transmitted to the delay buffer 81 without being delayed. Accordingly, using on-off control performed on the switches 84 to 87, the delay time of the clock signal 16 can be adjusted so as to be in the range from 0 ps to 4 ps.

Regarding FIG. 10B, a column 31 indicates a logical state of the signal 63A for controlling the switch 84. A column 32 indicates a logical state of the signal 63B for controlling the switch 85. A column 33 indicates a logical state of the signal 63C for controlling the switch 86. A column 34 indicates a logical state of the signal 63D for controlling the switch 87. A column 35 indicates a transmission delay time, which is to be generated in the delay adjustment unit 61, of the clock signal 16. In each of the columns 31 to 34, the logical value “1” indicates that a corresponding one of the switches 84 to 87 is in the on-state, and the logical value “0” indicates that a corresponding one of the switches 84 to 87 is in the off-state.

A row 36 indicates that, when each of the switches 84 to 87 is in the on-state, the delay time, which is to be generated in the delay adjustment unit 61, of the clock signal 16 is 0 ps. A row 37 indicates that, when each of the switches 84 to 87 is in the off-state, the delay time, which is to be generated in the delay adjustment unit 61, of the clock signal 16 is 4 ps. Accordingly, by controlling each of the switches 84 to 87 to be turned on or turned off, the controller 60 can adjust the delay time that is to be generated in the delay adjustment unit 61 so that the delay time is in the range from 0 ps to 4 ps.

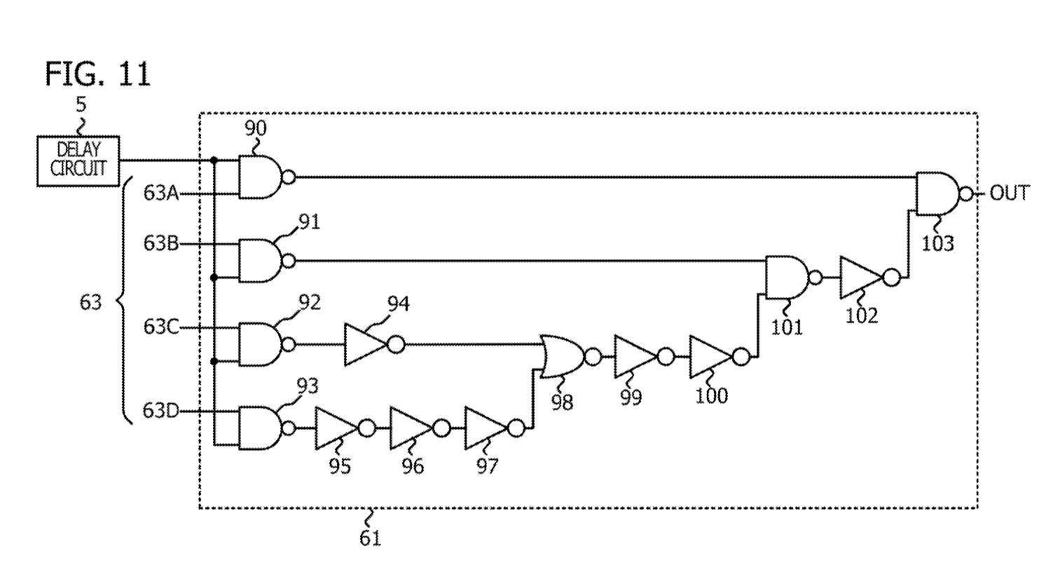

FIG. 11 is a circuit diagram of a delay adjustment unit 61 according to another embodiment. In FIG. 11, the delay adjustment unit 61 includes NAND circuits 90 to 93, 101, and 103, inverters 94 to 97, 99, 100, and 102, and a NOR circuit 98. Note that, because the delay adjustment unit 62 may have a configuration which is similar to that of the delay adjustment unit 61, a description thereof is omitted.

The NAND circuit 90 takes an output signal of the delay circuit 5 and the signal 63A as inputs. The NAND circuit 90 performs logical inversion on the AND of the two inputs to obtain an inverted signal, and outputs the inverted signal as an output signal. The NAND circuit 91 takes the output signal of the delay circuit 5 and the signal 63B as inputs. The NAND circuit 91 performs logical inversion on the AND of the two inputs to obtain an inverted signal, and outputs the inverted signal as an output signal. The NAND circuit 92 takes the output signal of the delay circuit 5 and the signal 63C as inputs. The NAND circuit 92 performs logical inversion on the AND of the two inputs to obtain an inverted signal, and outputs the inverted signal as an output signal. The NAND circuit 93 takes the output signal of the delay circuit 5 and the signal 63D as inputs. The NAND circuit 93 performs logical inversion on the AND of the two inputs to obtain an inverted signal, and outputs the inverted signal as an output signal.

The inverter 94 performs logical inversion on the output signal of the NAND circuit 92 to obtain an inverted signal, and outputs the inverted signal as an output signal. The inverter 95 performs logical inversion on the output signal of the NAND circuit 93 to obtain an inverted signal, and outputs the inverted signal as an output signal. The inverter 96 performs logical inversion on the output signal of the inverter 95 to obtain an inverted signal, and outputs the inverted signal as an output signal. The inverter 97 performs logical inversion on the output signal of the inverter 96 to obtain an inverted signal, and outputs the inverted signal as an output signal.

The NOR circuit 98 takes the output signal of the inverter 94 and the output signal of the inverter 97 as inputs. The NOR circuit 98 performs logical inversion on the OR of the two signals to obtain an inverted signal, and outputs the inverted signal as an output signal. The inverter 99 performs logical inversion on the output signal of the NOR circuit 98 to obtain an inverted signal, and outputs the inverted signal as an output signal. The inverter 100 performs logical inversion on the output signal of the inverter 99 to obtain an inverted signal, and outputs the inverted signal as an output signal.

The NAND circuit 101 takes the output signal of the NAND circuit 91 and the output signal of the inverter 100 as inputs. The NAND circuit 101 performs logical inversion on the AND of the two signals to obtain an inverted signal, and outputs the inverted signal as an output signal. The inverter 102 performs logical inversion on the output signal of the NAND circuit 101 to obtain an inverted signal, and outputs the inverted signal as an output signal.

The NAND circuit 103 takes the output signal of the NAND circuit 90 and the output signal of the inverter 102 as inputs. The NAND circuit 103 performs logical inversion on the AND of the two signals, which have been input, to obtain an inverted signal, and outputs the inverted signal as an output signal OUT. The output signal OUT of the NAND circuit 103 is input to the delay circuit 7.

When all of the logical values of the signals 63A to 63D are “0”, the output signal OUT always becomes “0” regardless of the logical value of the output signal of the delay circuit 5.

When the logical value of the signal 63A is “1” and the logical values of the signals 63B to 63D are “0”, the logical value of an input signal IN that is the output signal of the delay circuit 5 is transmitted through the NAND circuits 90 and 103 in this order to become the logical value of the output signal OUT. Accordingly, the input signal IN is delayed in accordance with the input and output delays of the NAND circuits 90 and 103.

When the logical value of the signal 63B is “1” and the logical values of the signals 63A, 63C, and 63D are “0”, the logical value of the input signal IN is transmitted through the NAND circuits 91 and 101, the inverter 102, and the NAND circuit 103 in this order to become the logical value of the output signal OUT. Accordingly, the input signal IN is delayed in accordance with the input and output delays of the NAND circuits 91 and 101, the inverter 102, and the NAND circuit 103.

When the logical value of the signal 63C is “1” and the logical values of the signals 63A, 63B, and 63D are “0”, the logical value of the input signal IN is transmitted through the NAND circuit 92, the inverter 94, the NOR circuit 98, the inverters 99 and 100, the NAND circuit 101, the inverter 102, and the NAND circuit 103 in this order to become the logical value of the output signal OUT. Accordingly, the input signal IN is delayed in accordance with the input and output delays of the NAND circuit 92, the inverter 94, the NOR circuit 98, the inverters 99 and 100, the NAND circuit 101, the inverter 102, and the NAND circuit 103.

When the logical value of the signal 63D is “1” and the logical values of the signals 63A, 63B, and 63C are “0”, the logical value of the input signal IN is transmitted through the NAND circuit 93, the inverters 95 to 97, the NOR circuit 98, the inverters 99 and 100, the NAND circuit 101, the inverter 102, and the NAND circuit 103 in this order to become the logical value of the output signal OUT. Accordingly, the input signal IN is delayed in accordance with the input and output delays of the NAND circuit 93, the inverters 95 to 97, the NOR circuit 98, the inverters 99 and 100, the NAND circuit 101, the inverter 102, and the NAND circuit 103.

As described above, the delay adjustment unit 61 can change, in accordance with the logical values of the signals 63A to 63D, a time that is taken for the logical value of the input signal IN to become the logical value of the output signal OUT. Accordingly, the delay adjustment unit 61 illustrated in FIG. 11 operates as a circuit that can adjust the delay time using the adjustment signal 63.

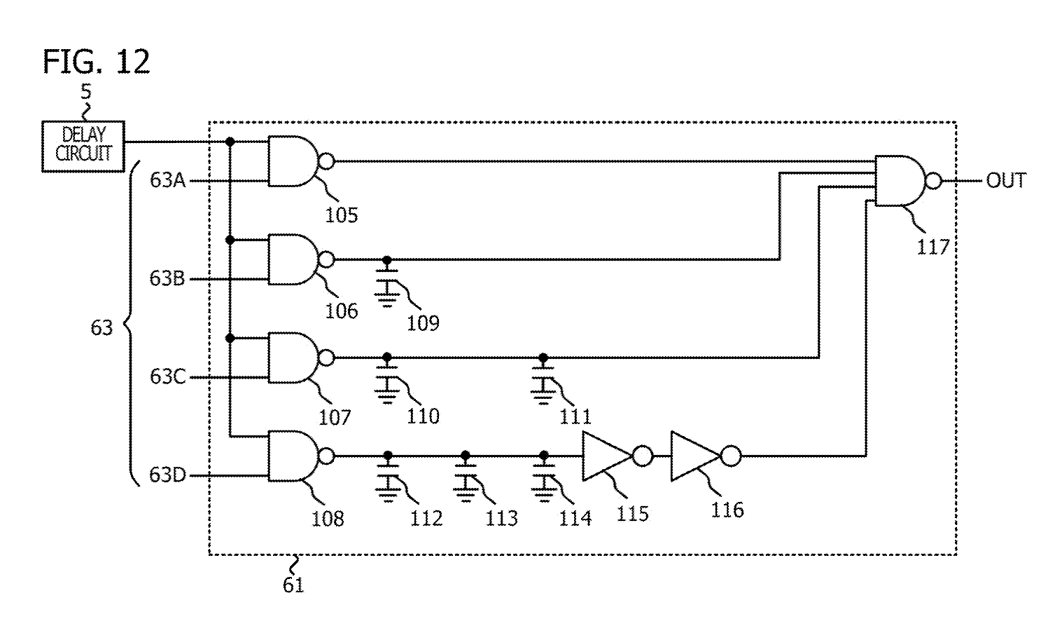

FIG. 12 is a circuit diagram of a delay adjustment unit 61 according to another embodiment. In FIG. 12, the delay adjustment unit 61 includes NAND circuits 105 to 108 and 117, inverters 115 and 116, and capacitors 109 to 114. Note that, because the delay adjustment unit 62 may have a configuration which is similar to that of the delay adjustment unit 61, a description thereof is omitted.

The NAND circuit 105 takes the output signal of the delay circuit 5, which is the input signal IN, and the signal 63A as inputs. The NAND circuit 105 performs logical inversion on the AND of the two inputs to obtain an inverted signal, and outputs the inverted signal as an output signal. The NAND circuit 106 takes the output signal of the delay circuit 5 and the signal 63B as inputs. The NAND circuit 106 performs logical inversion on the AND of the two inputs to obtain an inverted signal, and outputs the inverted signal as an output signal. The NAND circuit 107 takes the output signal of the delay circuit 5 and the signal 63C as inputs. The NAND circuit 107 performs logical inversion on the AND of the two inputs to obtain an inverted signal, and outputs the inverted signal as an output signal. The NAND circuit 108 takes the output signal of the delay circuit 5 and the signal 63D as inputs. The NAND circuit 108 performs logical inversion on the AND of the two inputs to obtain an inverted signal, and outputs the inverted signal as an output signal.

The capacitor 109 delays the output signal of the NAND circuit 106. The transmission delay time of the output signal that is delayed by the capacitor 109 increases with the capacitance value of the capacitor 109. Similarly, the capacitors 110 to 114 delay the output signals of the NAND circuits 106 to 108, respectively, and the output signals are transmitted. When the capacitance values of the individual capacitors are the same, the transmission delay time of the output signal of the NAND circuit 107 which is connected to the capacitors 110 and 111 is longer than that of the output signal of the NAND circuit 106 which is connected to the capacitor 109.

The inverters 115 and 116 further delay the output signal that has been delayed by the capacitors 112 to 114. When the gradient of the output signal of the NAND circuit 108 is increased too much by the capacitors 112 to 114, there is a case in which the voltage value of the output signal is not reduced to a level with which the logical value of the output signal can be determined. The inverters 115 and 116 can reduce the gradient, which has been increased by the capacitors 112 to 114, of the output signal of the NAND circuit 108.

When all of the logical values of the signals 63A to 63D are “0”, the output signal OUT always becomes “0” regardless of the logical value of the output signal of the delay circuit 5.

When the logical value of the signal 63A is “1” and the logical values of the signals 63B to 63D are “0”, the logical value of the input signal IN is transmitted through the NAND circuits 105 and 117 in this order to become the logical value of the output signal OUT. Accordingly, the input signal IN is delayed in accordance with the input and output delays of the NAND circuits 105 and 117.

When the logical value of the signal 63B is “1” and the logical values of the signals 63A, 63C, and 63D are “0”, the logical value of the input signal IN is transmitted through the NAND circuit 106, a node with the capacitor 109, and the NAND circuit 117 in this order to become the logical value of the output signal OUT.

Accordingly, the input signal IN is delayed in accordance with the input and output delays of the NAND circuits 105 and 117 and the capacitance value of the capacitor 109.

When the logical value of the signal 63C is “1” and the logical values of the signals 63A, 63B, and 63D are “0”, the logical value of the input signal IN is transmitted through the NAND circuit 106, nodes with the capacitors 110 and 111, and the NAND circuit 117 in this order to become the logical value of the output signal OUT. Accordingly, the input signal IN is delayed in accordance with the input and output delays of the NAND circuits 105 and 117 and the capacitance values of the capacitors 110 and 111.

When the logical value of the signal 63D is “1” and the logical values of the signals 63A, 63B, and 63C are “0”, the logical value of the input signal IN is transmitted through the NAND circuit 106, nodes with the capacitors 112 to 114, the inverters 115 and 116, and the NAND circuit 117 in this order to become the logical value of the output signal OUT. Accordingly, the input signal IN is delayed in accordance with the input and output delays of the NAND circuits 105 and 117 and the capacitance values of the capacitors 112 to 114.

As described above, the delay adjustment unit 61 can change, in accordance with the logical values of the signals 63A to 63D, a time that is taken for the logical value of the input signal IN to become the logical value of the output signal OUT. Accordingly, the delay adjustment unit 61 illustrated in FIG. 12 operates as a circuit that can adjust the delay time using the adjustment signal 63. Furthermore, the number of implemented elements can be reduced by adjusting the delay time using the capacitors, compared with the number of implemented elements illustrated in FIG. 11.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A time difference measurement apparatus for measuring a time difference between transmission delay times of signals transmitted on two signal lines, the time difference measurement apparatus comprising:
a selector for outputting one of the signals transmitted on the signal lines in accordance with a selection signal, the selector being connected to output ends of the two signal lines;
a switch connected to an output of the selector for outputting the selection signal in accordance with an output signal of the selector, the output signal being delayed for a predetermined time;
a feedback loop for connecting the output of the selector to input ends of the two signal lines; and
a controller connected to the feedback loop for calculating a time difference between transmission delay times of the signals transmitted on the two signal lines on the basis of self-oscillation cycles of signals transmitted through the feedback loop, the self-oscillation cycles changing in accordance with a logical value of the selection signal.

2. The time difference measurement apparatus according to claim 1,
wherein the switch fixes a logical value of the selection signal when the switch receives a switching signal having a predetermined value,
wherein the controller outputs the switching signal, measures the self-oscillation cycles of each signal transmitted through the feedback loop in accordance with a logical value of the switching signal, respectively, and calculates the time difference between the transmission delay times of each signal transmitted on the two signal lines on the basis of a difference between the self-oscillation cycles being measured.

3. The time difference measurement apparatus according to claim 1, wherein the two signal lines include an odd number of NOT circuits, respectively.

4. The time difference measurement apparatus according to claim 1, wherein the feedback loop includes one NOT circuit when the two signal lines include an even number of NOT circuits, respectively.

5. The time difference measurement apparatus according to claim 2, wherein the switch includes
a delay circuit for delaying the output signal of the selector by the predetermined time, and inverting the output signal of the selector, and
an OR circuit for outputting a logical sum of the output signal of the delay circuit and the switching signal as the selection signal.

6. The time difference measurement apparatus according to claim 2, wherein the switch includes
a NOT circuit for inverting the output signal of the selector,
a sequential circuit for outputting a signal whose logical value is the same as the inverted logical value of the output signal of the selector in accordance with timing at which a logical value of a trigger signal changes,
an AND circuit for outputting a logical product of the signals that have been transmitted on the two signal lines and the output signal of the selector,
a NOR circuit for outputting an inverted signal of a logical sum of the signals that have been transmitted on the two signal lines and the output signal of the selector,
a multiplexer for selecting and outputting either the output signal of the AND circuit or the output signal of the NOR circuit as the trigger signal in accordance with a logical value of an output signal of the sequential circuit, and
an OR circuit for outputting a logical sum of the output signal of the sequential circuit and the switching signal as the selection signal.

7. A time difference adjustment circuit for measuring a time difference between transmission delay times of signals that are transmitted on two signal lines, and for adjusting the transmission delay times of the signals on the basis of the time difference, the time difference adjustment circuit comprising:
a selector for outputting one of the signals transmitted on the signal lines in accordance with a selection signal;
a switch for delaying an output signal of the selector and outputting the delayed signal as the selection signal;
a feedback loop for connecting the output of the selector to the two signal lines; and
a controller for calculating a time difference between transmission delay times of each signal transmitted on each of the two signal lines on the basis of self-oscillation cycles of each signal transmitted through the feedback loop, the self-oscillation cycles changing in accordance with a logical value of the selection signal, and outputting a setting signal on the basis of the calculated time difference between the transmission delay times.

8. The time difference adjustment circuit according to claim 7,
wherein the switch fixes a logical value of the selection signal when the switch receives a switching signal of a predetermined value, and
wherein the controller outputs the switching signal, measures the self-oscillation cycles of each signal transmitted through the feedback loop in accordance with the logical value of the switching signal, respectively, and calculates the time difference between the transmission delay times of each signal transmitted on the two signal lines on the basis of a difference between the self-oscillation cycles being measured, respectively.

9. The time difference adjustment circuit according to claim 7, wherein the two signal lines include an odd number of NOT circuits, respectively.

10. The time difference adjustment circuit according to claim 7, wherein the controller includes:
a mode controller for outputting a switching signal for setting an operation mode,
a measurement unit for measuring each of the self-oscillation cycles in accordance with the operation mode which has been set by the switching signal, the operation mode being switched between a first mode and a second mode in accordance with the value of the switching signal,
a storage unit for storing the measured self-oscillation cycle in the first mode, and
a comparator for comparing a difference time between the self-oscillation cycle in the first mode and the self-oscillation cycle in the second mode to generate delay times of each signal that are transmitted on the two signal lines, respectively, outputting the setting signal in accordance with the delay times.
